(19) United States
(12) Patent Application Publication
(10) Pub. No.: US 2025/0226464 A1
(43) Pub. Date: Jul. 10, 2025

(54) METHOD OF MANUFACTURING ALL-SOLID-STATE BATTERY INCLUDING SILICON-BASED ANODE ACTIVE MATERIAL, METHOD OF OPERATING SAME, AND METHOD OF TESTING SAME

(71) Applicants: Hyundai Motor Company, Seoul (KR); Kia Corporation, Seoul (KR)

(72) Inventors: Seon Hwa Kim, Seoul (KR); Hong Suk Choi, Seoul (KR); Hee Soo Kang, Seoul (KR); Dong Hyun Cho, Seoul (KR); Jae Seok Nam, Seoul (KR); Jae Min Lim, Seoul (KR); So Yeon Kim, Seoul (KR)

(21) Appl. No.: 18/805,673

(22) Filed: Aug. 15, 2024

(30) Foreign Application Priority Data
Jan. 5, 2024 (KR) 10-2024-0001991

(51) Int. Cl. H01M 10/44; H01M 4/02; H01M 4/38; H01M 10/48

(52) U.S. Cl. CPC H01M 10/446; H01M 4/386; H01M 10/48; H01M 2004/027

(57) ABSTRACT

Disclosed are a method of manufacturing an all-solid-state battery including a silicon-based anode active material, and methods of operating and testing an all-solid-state battery manufactured by the manufacturing method.

### CROSS-REFERENCE TO RELATED APPLICATION

This application claims, under 35 U.S.C. § 119 (a), the benefit of Korean Patent Application No. 10-2024-0001991, filed on Jan. 5, 2024, the entire contents of which are incorporated herein by reference.

### BACKGROUND

### Technical Field

The present disclosure relates to a method of manufacturing an all-solid-state battery including a silicon-based anode active material, and methods of operating and testing an all-solid-state battery manufactured by the manufacturing method.

### Background

Silicon-based anode active materials have the advantage of high theoretical capacity compared to existing carbon-based anode active materials such as graphite. However, silicon-based anode active materials undergo large volume expansion during charging and discharging, which causes cracking of the solid electrolyte and electrodes.

With the goal of solving this problem, methods of inserting the battery into a fixed pressure jig and applying high pressure from the outside during charging and discharging of the battery are proposed. However, during charging and discharging, the battery undergoes repeated expansion and contraction, whereas the pressure jig is fixed, so there is a problem in that the pressure applied to the battery varies depending on SoC (state of charge). Non-uniform pressure changes may lead to cracking of the solid electrolyte and electrodes.

A variable pressure jig that is able to control the pressure applied from the outside may be applied, but the production cost of the battery may increase and also the volume of the battery may increase, which may lead to loss of energy density.

### SUMMARY

An object of the present disclosure is to provide a method of manufacturing an all-solid-state battery with low operating pressure.

The objects of the present disclosure are not limited to the foregoing. The objects of the present disclosure will be able to be clearly understood through the following description and to be realized by the means described in the claims and combinations thereof.

An exemplary embodiment of the present disclosure provides a method of manufacturing an all-solid-state battery, including preparing a cell including a cathode layer, an anode layer, and a solid electrolyte layer disposed between the cathode layer and the anode layer and activating the cell by charging and discharging under predetermined conditions while applying a pressure of 4.5 MPa or more to the cell.

The anode layer may include a silicon-based anode active material.

The anode layer may include 60 wt % to 80 wt % of a silicon-based anode active material, 10 wt % to 35 wt % of a solid electrolyte, and 1 wt % to 10 wt % of a binder.

The cell may have an N/P ratio of 2.0 or less but greater than 1.1.

Activating the cell may include performing charging and discharging at a voltage of 2.0 V to 4.25 V and a temperature of 30° C. to 50° C. while applying pressure to the cell.

Activating the cell may include subjecting the cell to 3 to 10 cycles of charging and discharging.

Activating the cell may include applying a pressure of 10 MPa or less to the cell.

Another exemplary embodiment of the present disclosure provides a method of operating an all-solid-state battery, including preparing an all-solid-state battery including a cathode layer, an anode layer, and a solid electrolyte layer interposed between the cathode layer and the anode layer, activating the all-solid-state battery by charging and discharging applying a pressure of 4.5 MPa or more to the all-solid-state battery, and operating the activated all-solid-state battery while applying a pressure of 4.5 MPa or less to the activated all-solid-state battery.

Operating the activated all-solid-state battery may include charging and discharging while applying a pressure of 2.5 MPa to 4.5 MPa to the activated all-solid-state battery.

Still another exemplary embodiment of the present disclosure provides a method of testing an all-solid-state battery, including preparing an all-solid-state battery including a cathode layer, an anode layer, and a solid electrolyte layer interposed between the cathode layer and the anode layer, activating the all-solid-state battery by charging and discharging while applying a pressure of 4.5 MPa or more to the all-solid-state battery, operating the activated all-solid-state battery while applying a pressure of 4.5 MPa or less to the activated all-solid-state battery, and determining whether the all-solid-state battery is defective or not by measuring a DC-IR (direct current-internal resistance) value of the operated all-solid-state battery.

In determining whether the all-solid-state battery is defective or not, the activated all-solid-state battery may be determined to be defective if the DC-IR value is 50Ω or more in the first-cycle discharging, after operating the activated all-solid-state battery.

### BRIEF DESCRIPTION OF THE DRAWINGS

The above and other features of the present disclosure will now be described in detail referring to certain exemplary embodiments thereof illustrated in the accompanying drawings, which are given hereinbelow by way of illustration only, and thus are not limitative of the present disclosure, and wherein:

FIG. 1 shows an all-solid-state battery according to the present disclosure;

FIG. 2 shows results of evaluation of the lifespan of all-solid-state batteries according to Example 1, Example 2, and Comparative Example 1;

FIG. 3 shows results of evaluation of the lifespan of all-solid-state batteries according to Example 1, Example 3, and Comparative Example 2; and

FIG. 4 shows results of evaluation of the lifespan of all-solid-state batteries according to Example 1, Example 4, and Comparative Example 3.

### DETAILED DESCRIPTION

The above and other objects, features and advantages of the present disclosure will be more clearly understood from the following preferred embodiments taken in conjunction with the accompanying drawings. However, the present disclosure is not limited to the embodiments disclosed herein, and may be modified into different forms. These embodiments are provided to thoroughly explain the disclosure and to sufficiently transfer the spirit of the present disclosure to those skilled in the art.

Throughout the drawings, the same reference numerals will refer to the same or like elements. For the sake of clarity of the present disclosure, the dimensions of structures are depicted as being larger than the actual sizes thereof. It will be understood that, although terms such as “first”, “second”, etc. may be used herein to describe various elements, these elements are not to be limited by these terms. These terms are only used to distinguish one element from another element. For instance, a “first” element discussed below could be termed a “second” element without departing from the scope of the present disclosure. Similarly, the “second” element could also be termed a “first” element. As used herein, the singular forms are intended to include the plural forms as well, unless the context clearly indicates otherwise.

It will be further understood that the terms “comprise”, “include”, “have”, etc., when used in this specification, specify the presence of stated features, integers, steps, operations, elements, components, or combinations thereof, but do not preclude the presence or addition of one or more other features, integers, steps, operations, elements, components, or combinations thereof. Also, it will be understood that when an element such as a layer, film, area, or sheet is referred to as being “on” another element, it may be directly on the other element, or intervening elements may be present therebetween. Similarly, when an element such as a layer, film, area, or sheet is referred to as being “under” another element, it may be directly under the other element, or intervening elements may be present therebetween.

The terminology used herein is for the purpose of describing particular embodiments only and is not intended to be limiting of the disclosure. As used herein, the singular forms “a,” “an” and “the” are intended to include the plural forms as well, unless the context clearly indicates otherwise. These terms are merely intended to distinguish one component from another component, and the terms do not limit the nature, sequence or order of the constituent components. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Throughout the specification, unless explicitly described to the contrary, the word “comprise” and variations such as “comprises” or “comprising” will be understood to imply the inclusion of stated elements but not the exclusion of any other elements. In addition, the terms “unit”, “-er”, “-or”, and “module” described in the specification mean units for processing at least one function and operation, and can be implemented by hardware components or software components and combinations thereof.

Although exemplary embodiment is described as using a plurality of units to perform the exemplary process, it is understood that the exemplary processes may also be performed by one or plurality of modules. Additionally, it is understood that the term controller/control unit refers to a hardware device that includes a memory and a processor and is specifically programmed to execute the processes described herein. The memory is configured to store the modules and the processor is specifically configured to execute said modules to perform one or more processes which are described further below.

Further, the control logic of the present disclosure may be embodied as non-transitory computer readable media on a computer readable medium containing executable program instructions executed by a processor, controller or the like. Examples of computer readable media include, but are not limited to, ROM, RAM, compact disc (CD)-ROMs, magnetic tapes, floppy disks, flash drives, smart cards and optical data storage devices. The computer readable medium can also be distributed in network coupled computer systems so that the computer readable media is stored and executed in a distributed fashion, e.g., by a telematics server or a Controller Area Network (CAN).

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about”.

In the present specification, when a range is described for a variable, it will be understood that the variable includes all values including the end points described within the stated range. For example, the range of “5 to 10” will be understood to include any subranges, such as 6 to 10, 7 to 10, 6 to 9, 7 to 9, and the like, as well as individual values of 5, 6, 7, 8, 9 and 10, and will also be understood to include any value between valid integers within the stated range, such as 5.5, 6.5, 7.5, 5.5 to 8.5, 6.5 to 9, and the like. Also, for example, the range of “10% to 30%” will be understood to include subranges, such as 10% to 15%, 12% to 18%, 20% to 30%, etc., as well as all integers including values of 10%, 11%, 12%, 13% and the like up to 30%, and will also be understood to include any value between valid integers within the stated range, such as 10.5%, 15.5%, 25.5%, and the like.

The term “binder”, as used herein, refers to a resin or a polymeric material that can be polymerized or cured to form a polymeric matrix. The binder may be cured (polymerized) or partially cured upon curing process such as heating, UV radiation, electron beaming, chemical polymerization using additives and the like.

A term “all-solid-state battery” as used herein refers to a rechargeable secondary battery that includes an electrolyte in a solid state, e.g., gel or polymer (cured), which may include an ionomer and other electrolytic components for transferring ions between the electrodes of the battery.

Unless otherwise specified, all numbers, values, and/or representations that express the amounts of components, reaction conditions, polymer compositions, and mixtures used herein are to be taken as approximations including various uncertainties affecting measurement that inherently occur in obtaining these values, among others, and thus should be understood to be modified by the term “about” in all cases. Furthermore, when a numerical range is disclosed in this specification, the range is continuous, and includes all values from the minimum value of said range to the maximum value thereof, unless otherwise indicated. Moreover, when such a range pertains to integer values, all integers including the minimum value to the maximum value are included, unless otherwise indicated.

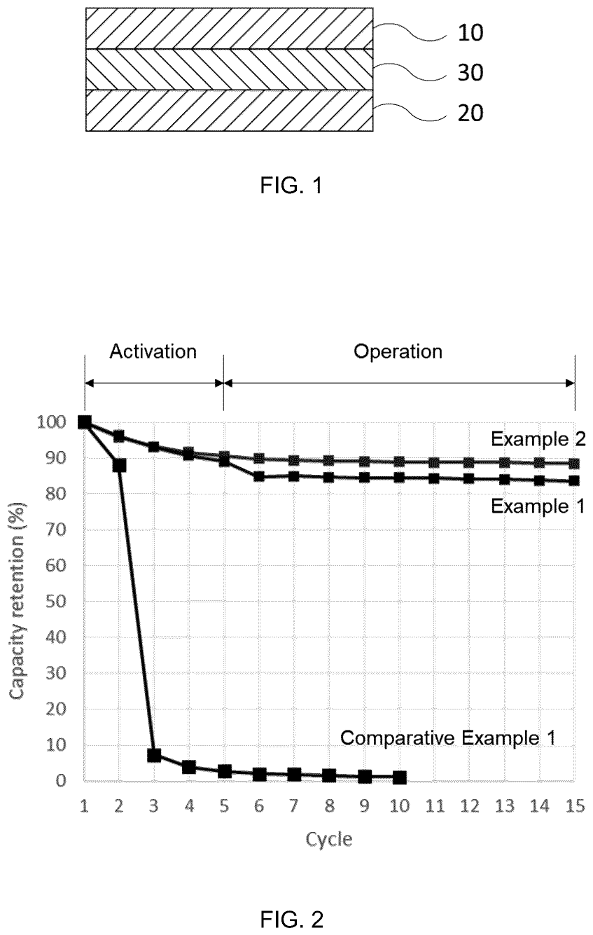

FIG. 1 shows an all-solid-state battery according to the present disclosure. Hereinafter, “cell” and “all-solid-state battery” may refer to an object with a layered structure including a cathode layer 10, an anode layer 20, and a solid electrolyte layer 30 disposed between the cathode layer 10 and the anode layer 20, as shown in FIG. 1. Taking into consideration the context of each term, it will be able to clearly understand what “cell” and “all-solid-state battery” mean.

The method of manufacturing the all-solid-state battery may include preparing a cell including a cathode layer 10, an anode layer 20, and a solid electrolyte layer 30 disposed between the cathode layer 10 and the anode layer 20, and activating the cell by pressing the cell at high pressure and charging and discharging the same under predetermined conditions.

In the present disclosure, when activating a cell including an anode layer 20 that includes a silicon-based anode active material and undergoes large volume expansion during charging and discharging, the cell is pressed at a higher pressure than before. Since the volume change is large in the activation step corresponding to early charging and discharging, high pressure may be applied to the cell, preventing cracking. Since the volume change is small in the operating step after activation, the cell may be driven stably even under lower pressure than in the activation step.

Even when high pressure is applied in the activation step, there is a high possibility of cracking in the operating step because the volume change is large in cases in which utilization of the anode active material is high. Accordingly, the present disclosure is characterized by appropriately adjusting the N/P ratio of the cell to enable the cell to be driven more stably.

The cathode layer 10 may include a cathode active material, a solid electrolyte, a conductive material, and a binder.

The cathode active material may include a lithium transition metal oxide capable of storing and releasing lithium.

The lithium transition metal oxide may include any material that is common in the technical field to which the present disclosure belongs. For example, the lithium transition metal oxide may include LiNiₓ₁Coₓ₂Mnₓ₃O₂ (0.65≤x1≤0.85, 0.05<x2<0.25, 0.03<x3<0.2, and x1+x2+x3=1).

The average particle diameter D50 of the cathode active material is not particularly limited, and may be, for example, 1 μm to 20 μm. The average particle diameter D50 of the cathode active material may be measured using a commercially available laser diffraction scattering-type particle size distribution analyzer, for example, a Microtrac particle size distribution analyzer. Alternatively, 200 particles may be randomly extracted from the electron micrograph and the average particle diameter thereof may be calculated.

The cathode active material may be coated with an alkali metal oxide.

The alkali metal oxide may include an alkali metal element, a transition metal element, and a substitution element.

The alkali metal element may include at least one selected from the group consisting of lithium (Li), sodium (Na), potassium (K), and combinations thereof. Preferably, the alkali metal element includes lithium (Li).

The transition metal element may include any metal contained in alkali metal oxides commonly used in the technical field to which the present disclosure belongs. For example, the transition metal element may include at least one selected from the group consisting of niobium (Nb), tantalum (Ta), zirconium (Zr), and combinations thereof.

The solid electrolyte may be responsible for movement of lithium ions in the cathode layer 10.

The solid electrolyte may include at least one selected from the group consisting of an oxide-based solid electrolyte, a sulfide-based solid electrolyte, and combinations thereof. Also, the solid electrolyte may be crystalline, amorphous, or in a mixed state thereof.

Examples of the oxide-based solid electrolyte may include perovskite-type LLTO (Li₃ₓLa_{2/3-x}TiO₃), phosphate-based NASICON-type LATP (Li₁₊ₓAlₓTi₂₋ₓ(PO₄)₃), and the like.

Examples of the sulfide-based solid electrolyte may include Li₂S—P₂S₅, Li₂S—P₂S₅—LiI, Li₂S—P₂S₅—LiCl, Li₂S—P₂S₅—LiBr, Li₂S—P₂S₅—Li₂O, Li₂S—P₂S₅—Li₂O—LiI, Li₂S—SiS₂, Li₂S—SiS₂—LiI, Li₂S—SiS₂—LiBr, Li₂S—SiS₂—LiCl, Li₂S—SiS₂—B₂S₃—LiI, Li₂S—SiS₂—P₂S₅—LiI, Li₂S—B₂S₃, Li₂S—P₂S₅—ZₘSₙ (in which m and n are positive numbers, and Z is any one selected from among Ge, Zn, and Ga), Li₂S—GeS₂, Li₂S—SiS₂—Li₃PO₄, Li₂S—SiS₂-LiₓMO_{y} (in which x and y are positive numbers, and M is any one selected from among P, Si, Ge, B, Al, Ga, and In), Li₁₀GeP₂S₁₂, and the like.

Preferably, the solid electrolyte may include a sulfide-based solid electrolyte having an argyrodite crystal structure. The sulfide-based solid electrolyte having the argyrodite crystal structure may include at least one selected from the group consisting of Li_{7-y}PS_{6-y}Ha_{y} (in which Ha includes Cl, Br, or I and y satisfies 0<y≤2), Li_{7-z}PS_{6-z}(Ha1_{1-b}Ha2_{b})_{z} (in which Ha1 and Ha2 are different from each other, each independently includes Cl, Br or I, and b and z satisfy 0<b<1 and 0<z≤2), and combinations thereof.

Examples of the conductive material may include carbon black, conductive graphite, ethylene black, graphene, carbon nanotubes, carbon nanofiber, vapor grown carbon fiber, and the like.

Examples of the binder may include butadiene rubber, nitrile butadiene rubber, hydrogenated nitrile butadiene rubber, polyvinylidene fluoride (PVDF), polytetrafluoroethylene (PTFE), carboxymethyl cellulose (CMC), and the like. The binder may exist in a granular or linear form in the cathode layer 10.

The cathode layer 10 may include 70 wt % to 90 wt % of the cathode active material, 10 wt % to 15 wt % of the solid electrolyte, 1 wt % to 5 wt % of the conductive material, and 1 wt % to 5 wt % of the binder. Here, the amount of each component may be appropriately adjusted in consideration of the capacity, efficiency, etc. of an all-solid-state battery.

The thickness of the cathode layer 10 is not particularly limited, but may be 1 μm to 100 μm. The thickness of the cathode layer 10 may indicate an average value when a measurement target is measured at 5 points. Also, the thickness of the cathode layer 10 may indicate the thickness of the all-solid-state battery that is discharged.

The anode layer 20 may include an anode active material, a solid electrolyte, and a binder.

The anode active material may include a silicon-based anode active material. The silicon-based anode active material may include at least one selected from the group consisting of Si, SiOₓ (0<x<2), Si-containing alloys, and combinations thereof. The Si-containing alloy may include an alloy of Si and any metal selected from among alkali metals, alkaline earth metals, Group 13 elements, Group 14 elements, transition metals, rare earth elements, and combinations thereof.

The anode active material may include a silicon-based anode active material and a carbon-based anode active material. The carbon-based anode active material may include graphite such as mesocarbon microbeads (MCMB), highly oriented pyrolytic graphite (HOPG), etc., or amorphous carbon such as hard carbon and soft carbon.

The anode active material may be a composite of the carbon active material and the metal active material. For example, the surface of the carbon active material may be coated with the metal active material, or the surface of the metal active material may be coated with the carbon active material.

The solid electrolyte may be the same as or different from the solid electrolyte of the cathode layer 10. The solid electrolyte may include at least one selected from the group consisting of an oxide-based solid electrolyte, a sulfide-based solid electrolyte, and combinations thereof. Also, the solid electrolyte may be crystalline, amorphous, or in a mixed state thereof.

Examples of the oxide-based solid electrolyte may include perovskite-type LLTO (Li₃ₓLa_{2/3-x}TiO₃), phosphate-based NASICON-type LATP (Li₁₊ₓAlₓTi₂₋ₓ(PO₄)₃), and the like.

Examples of the sulfide-based solid electrolyte may include Li₂S—P₂S₅, Li₂S—P₂S₅—LiI, Li₂S—P₂S₅—LiCl, Li₂S—P₂S₅—LiBr, Li₂S—P₂S₅—Li₂O, Li₂S—P₂S₅—Li₂O—LiI, Li₂S—SiS₂, Li₂S—SiS₂—LiI, Li₂S—SiS₂—LiBr, Li₂S—SiS₂—LiCl, Li₂S—SiS₂—B₂S₃—LiI, Li₂S—SiS₂—P₂S₅—LiI, Li₂S—B₂S₃, Li₂S—P₂S₅—ZₘSₙ (in which m and n are positive numbers, and Z is any one selected from among Ge, Zn, and Ga), Li₂S—GeS₂, Li₂S—SiS₂—Li₃PO₄, Li₂S—SiS₂-LiₓMO_{y} (in which x and y are positive numbers, and M is any one selected from among P, Si, Ge, B, Al, Ga, and In), Li₁₀GeP₂S₁₂, and the like.

Preferably, the solid electrolyte may include a sulfide-based solid electrolyte having an argyrodite crystal structure. The sulfide-based solid electrolyte having the argyrodite crystal structure may include at least one selected from the group consisting of Li_{7-y}PS_{6-y}Ha_{y} (in which Ha includes Cl, Br, or I and y satisfies 0<y≤2), Li_{7-z}PS_{6-z}(Ha1_{1-b}Ha2_{b})_{z} (in which Ha1 and Ha2 are different from each other, each independently includes Cl, Br or I, and b and z satisfy 0<b<1 and 0<z$2), and combinations thereof.

The binder may be the same as or different from the binder of the cathode layer 10. Examples of the binder may include butadiene rubber, nitrile butadiene rubber, hydrogenated nitrile butadiene rubber, polyvinylidene fluoride (PVDF), polytetrafluoroethylene (PTFE), carboxymethyl cellulose (CMC), and the like. The binder may exist in a granular or linear form in the anode layer 20.

The anode layer 20 may include 60 wt % to 80 wt % of the silicon-based anode active material, 10 wt % to 35 wt % of the solid electrolyte, and 1 wt % to 10 wt % of the binder.

The thickness of the anode layer 20 is not particularly limited, but may be 1 μm to 100 μm. The thickness of the anode layer 20 may indicate an average value when a measurement target is measured at 5 points. Also, the thickness of the anode layer 20 may indicate the thickness of the all-solid-state battery that is discharged.

The solid electrolyte layer 30 may have a sheet shape having at least two opposing major surfaces. Each of the two major surfaces may include not only a mathematical plane, but also a certain curved surface in part, and may have irregularities generated during formation of the solid electrolyte layer 30. In this sense, the sheet shape is not limited to a relatively thin cuboid.

In the sheet-shaped solid electrolyte layer 30, the distance between two opposing major surfaces may be the thickness of the solid electrolyte layer 30. The length of the solid electrolyte layer 30 in the first direction (e.g., width direction) perpendicular to the thickness direction is greater than the thickness. Also, the length of the solid electrolyte layer 30 in the second direction (e.g., longitudinal direction) perpendicular to the thickness direction and the first direction is greater than the thickness.

The thickness of the solid electrolyte layer 30 is not particularly limited, but may be 1 μm to 100 μm. The thickness of the solid electrolyte layer 30 may indicate an average value when a measurement target is measured at 5 points.

The solid electrolyte layer 30 may include a solid electrolyte with lithium ion conductivity and a binder.

The solid electrolyte may be the same as or different from the solid electrolyte of the cathode layer 10 and/or the anode layer 20. The solid electrolyte may include at least one selected from the group consisting of an oxide-based solid electrolyte, a sulfide-based solid electrolyte, and combinations thereof. Also, the solid electrolyte may be crystalline, amorphous, or in a mixed state thereof.

Examples of the oxide-based solid electrolyte may include perovskite-type LLTO (Li₃ₓLa_{2/3-x}TiO₃), phosphate-based NASICON-type LATP (Li₁₊ₓAlₓTi₂₋ₓ(PO₄)₃), and the like.

Examples of the sulfide-based solid electrolyte may include Li₂S—P₂S₅, Li₂S—P₂S₅—LiI, Li₂S—P₂S₅—LiCl, Li₂S—P₂S₅—LiBr, Li₂S—P₂S₅—Li₂O, Li₂S—P₂S₅—Li₂O—LiI, Li₂S—SiS₂, Li₂S—SiS₂—LiI, Li₂S—SiS₂—LiBr, Li₂S—SiS₂—LiCl, Li₂S—SiS₂—B₂S₃—LiI, Li₂S—SiS₂—P₂S₅—LiI, Li₂S—B₂S₃, Li₂S—P₂S₅—ZₘSₙ (in which m and n are positive numbers, and Z is any one selected from among Ge, Zn, and Ga), Li₂S—GeS₂, Li₂S—SiS₂—Li₃PO₄, Li₂S—SiS₂-LiₓMO_{y} (in which x and y are positive numbers, and M is any one selected from among P, Si, Ge, B, Al, Ga, and In), Li₁₀GeP₂S₁₂, and the like.

Preferably, the solid electrolyte may include a sulfide-based solid electrolyte having an argyrodite crystal structure. The sulfide-based solid electrolyte having the argyrodite crystal structure may include at least one selected from the group consisting of Li_{7-y}PS_{6-y}Ha_{y} (in which Ha includes Cl, Br, or I and y satisfies 0<y≤2), Li_{7-z}PS_{6-z}(Ha1_{1-b}Ha2_{b}) z (in which Ha1 and Ha2 are different from each other, each independently includes Cl, Br or I, and b and z satisfy 0<b<1 and 0<z≤2), and combinations thereof.

The binder may be the same as or different from the binder of the cathode layer 10 and/or the anode layer 20. Examples of the binder may include butadiene rubber, nitrile butadiene rubber, hydrogenated nitrile butadiene rubber, polyvinylidene fluoride (PVDF), polytetrafluoroethylene (PTFE), carboxymethyl cellulose (CMC), and the like. The binder may exist in a granular or linear form in the solid electrolyte layer 30.

The cell may have an N/P ratio of 2.0 or less but greater than 1.1. The N/P ratio may indicate a value obtained by dividing the total capacity of the anode layer 20 by the total capacity of the cathode layer 10. If the N/P ratio is 1.1 or less, the change in volume may become large due to high utilization of the silicon-based anode active material, and thus, the all-solid-state battery may crack during operating even after activation at high pressure. On the other hand, if the N/P ratio exceeds 2.0, cell resistance and energy density loss may increase.

The method of preparing the cell is not particularly limited. For example, each layer may be formed by a wet process in which a slurry including the components of each layer is applied onto a substrate and dried, a dry process in which powder including the components of each layer is pressed, etc. Also, each layer may be formed at the same time or at different times. For example, the solid electrolyte layer 30 and the cathode layer 10 may be formed by direct application on the anode layer 20, or each layer may be manufactured separately and then celled in the structure shown in FIG. 1.

The method of manufacturing an all-solid-state battery according to the present disclosure may include activating the cell manufactured as above by pressing at high pressure and charging and discharging.

The activation step may include applying a pressure of 4.5 MPa to 10 MPa to the cell and charging and discharging under predetermined conditions. If the pressure applied in the activation step is less than 4.5 MPa, the change in volume of the silicon-based anode active material cannot be suppressed, whereas if it exceeds 10 MPa, the pressure may be too high and the cell may crack.

The activation step may include charging and discharging the cell at a voltage of 2.0 V to 4.25 V and a temperature of 30° C. to 50° C. Also, the activation step may include subjecting the cell to 3 to 10 cycles of charging and discharging.

The all-solid-state battery manufactured as above enables stable charging and discharging even at low pressure during actual operating because the volume change of the silicon-based anode active material is controlled.

The method of operating an all-solid-state battery according to the present disclosure may include preparing an all-solid-state battery including a cathode layer 10, an anode layer 20, and a solid electrolyte layer 30 interposed between the cathode layer 10 and the anode layer 20, activating the all-solid-state battery by charging and discharging applying a pressure of 4.5 MPa or more to the all-solid-state battery, and operating the activated all-solid-state battery while applying a pressure of 4.5 MPa or less to the activated all-solid-state battery.

Preparing and activating the all-solid-state battery are as described above, and a detailed description thereof will be omitted below.

Operating the all-solid-state battery may include applying a pressure of 2.5 MPa to 4.5 MPa to the activated all-solid-state battery and charging and discharging. If the pressure applied in the operating step is less than 2.5 MPa, the volume change of the silicon-based anode active material that occurs during operating cannot be effectively suppressed.

The method of testing an all-solid-state battery according to the present disclosure may include preparing an all-solid-state battery including a cathode layer 10, an anode layer 20, and a solid electrolyte layer 30 interposed between the cathode layer 10 and the anode layer 20, activating the all-solid-state battery by charging and discharging while applying a pressure of 4.5 MPa or more to the all-solid-state battery, operating the activated all-solid-state battery while applying a pressure of 4.5 MPa or less to the activated all-solid-state battery, and determining whether the all-solid-state battery is defective or not by measuring the DC-IR (direct current-internal resistance) value of the operated all-solid-state battery.

Preparing, activating, and operating the all-solid-state battery are as described above, and a detailed description thereof will be omitted below.

In determining whether the all-solid-state battery is defective or not, the activated all-solid-state battery may be determined to be defective if the DC-IR value is 50Ω or more in the first-cycle discharging, after operating the activated all-solid-state battery. If the pressure is insufficient or the number of charging and discharging cycles is insufficient in activating the all-solid-state battery, the electrode volume expansion may occur greatly in the operating step, causing electrode defects, resulting in shortened lifespan of the all-solid-state battery.

A better understanding of the present disclosure may be obtained through the following examples. These examples are merely set forth to illustrate the present disclosure, and are not to be construed as limiting the scope of the present disclosure.

### Example 1

A cell including an anode layer including a silicon-based anode active material, a cathode layer, and a solid electrolyte layer, as shown in FIG. 1, was prepared. The N/P ratio of the cell was adjusted to about 1.3.

The cell was activated by performing 5 cycles of charging and discharging under conditions of 0.2 C in a voltage range of about 2.0 V to 4.25 V while applying a pressure of 4.5 MPa to the cell.

The lifespan was measured by performing charging and discharging under conditions of 0.2 C in a voltage range of about 2.0 V to 4.25 V while applying a pressure of 2.5 MPa to the activated cell. The results thereof are shown in FIG. 2.

### Example 2

The lifespan was measured in the same manner as in Example 1, with the exception that a pressure of 4.5 MPa was applied to the activated cell. The results thereof are shown in FIG. 2.

### Comparative Example 1

The lifespan was measured in the same manner as in Example 1, with the exception that the cell was activated while applying a pressure of 2.5 MPa thereto, and a pressure of 2.5 MPa was applied to the activated cell. The results thereof are shown in FIG. 2.

Referring to FIG. 2, the lifespan of Examples 1 and 2 activated at high pressure was much longer than that of Comparative Example 1 activated at low pressure.

### Example 3

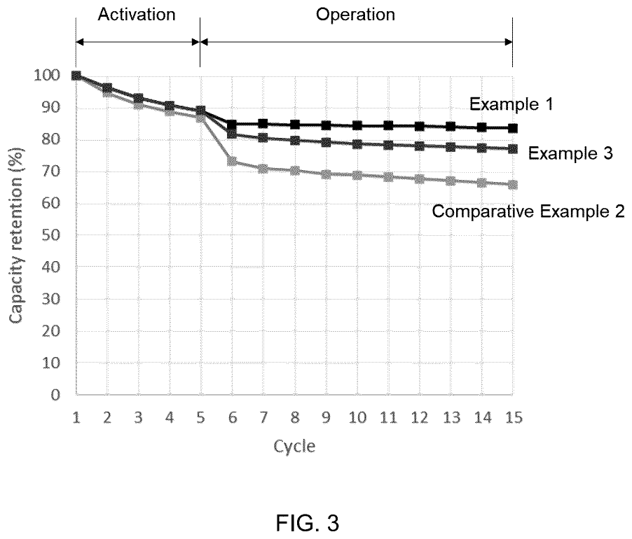

The lifespan was measured in the same manner as in Example 1, with the exception that the N/P ratio of the cell was adjusted to 2.0. The results thereof are shown in FIG. 3.

### Comparative Example 2

The lifespan was measured in the same manner as in Example 1, with the exception that the N/P ratio of the cell was adjusted to 1.1. The results thereof are shown in FIG. 3.

Referring to FIG. 3, if the N/P ratio of the cell was 1.1 or less even upon activation at high pressure, the capacity retention was low. Examples 1 and 3, in which the N/P ratio of the cell is 2.0 or less but greater than 1.1, showed a capacity retention of about 80% even after 15 cycles of charging and discharging.

### Example 4

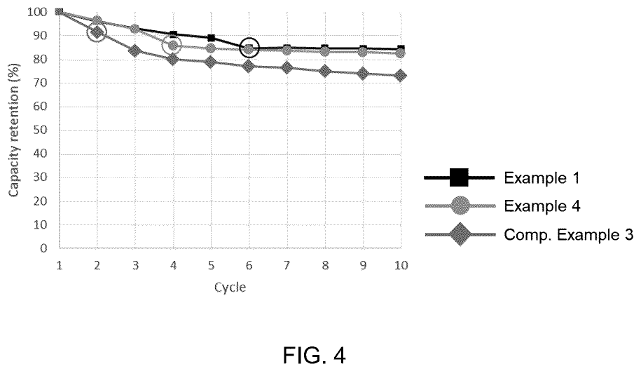

The lifespan was measured in the same manner as in Example 1, with the exception that the cell was activated by performing 3 cycles of charging and discharging under conditions of 0.2 C in a voltage range of about 2.0 V to 4.25 V while applying a pressure of 4.5 MPa thereto. The results thereof are shown in FIG. 4.

### Comparative Example 3

The lifespan was measured in the same manner as in Example 1, with the exception that the cell was activated by performing 1 cycle of charging and discharging under conditions of 0.2 C in a voltage range of about 2.0 V to 4.25 V while applying a pressure of 4.5 MPa. The results thereof are shown in FIG. 4.

FIG. 4 shows results of evaluation of the lifespan of the all-solid-state batteries according to Examples 1 and 4 and Comparative Example 3. Also, Table 1 below shows results of measurement of DC-IR values in the first-cycle discharging during operating in the all-solid-state batteries according to Examples 1 and 4 and Comparative Example 3. DC-IR was measured under conditions of SoC of 50% and 10 seconds during discharging.

TABLE 1

| Classification | DC-IR [Ω] |
|---|---|
| Comparative Example 3 | 59.20 |
| Example 4 | 24.46 |
| Example 1 | 25.83 |

Referring to FIG. 4 and Table 1, in Comparative Example 3, the number of charging and discharging cycles during activation was insufficient, so that the DC-IR value was 50Ω or more in the first-cycle discharging during operating, and accordingly, the capacity retention thereof was much lower than that of Example 1 and Example 4. Therefore, whether the activation step was sufficiently performed was determined based on the DC-IR value, and whether the all-solid-state battery was defective or not was determined based on the result thereof.

According to the present disclosure, an all-solid-state battery with low operating pressure can be obtained.

The effects of the present disclosure are not limited to the above-mentioned effects. It should be understood that the effects of the present disclosure include all effects that can be inferred from the description of the present disclosure.

As the examples of the present disclosure have been described in detail above, the scope of the present disclosure is not limited to the aforementioned examples, and various modifications and improvements made by those skilled in the art using the basic concept of the present disclosure defined in the following claims are also within the scope of the present disclosure.

What is claimed is:

1. A method of manufacturing an all-solid-state battery, the method comprising:
preparing a cell comprising a cathode layer, an anode layer, and a solid electrolyte layer disposed between the cathode layer and the anode layer; and
activating the cell by charging and discharging while applying a pressure of about 4.5 MPa or more to the cell.

2. The method of claim 1, wherein the anode layer comprises:
about 60 wt % to about 80 wt % of a silicon-based anode active material,
about 10 wt % to about 35 wt % of a solid electrolyte, and
about 1 wt % to about 10 wt % of a binder.

3. The method of claim 1, wherein the cell has an N/P ratio of about 2.0 or less but greater than about 1.1.

4. The method of claim 1, wherein activating the cell comprises applying pressure to the cell and charging and discharging at a voltage of about 2.0 V to about 4.25 V and a temperature of about 30° C. to about 50° C.

5. The method of claim 1, wherein activating the cell comprises subjecting the cell to 3 to 10 cycles of charging and discharging.

6. The method of claim 1, wherein activating the cell comprises applying a pressure of about 10 MPa or less to the cell.

7. A method of operating an all-solid-state battery, the method comprising:
preparing an all-solid-state battery comprising a cathode layer, an anode layer, and a solid electrolyte layer interposed between the cathode layer and the anode layer;
activating the all-solid-state battery by charging and discharging while applying a pressure of about 4.5 MPa or more to the cell; and
operating an activated all-solid-state battery while applying a pressure of 4.5 MPa or less to the activated all-solid-state battery.

8. The method of claim 7, wherein the anode layer comprises:
about 60 wt % to about 80 wt % of a silicon-based anode active material,
about 10 wt % to about 35 wt % of a solid electrolyte, and
about 1 wt % to about 10 wt % of a binder.

9. The method of claim 7, wherein the all-solid-state battery has an N/P ratio of about 2.0 or less but greater than about 1.1.

10. The method of claim 7, wherein activating the all-solid-state battery comprises applying pressure to the all-solid-state battery and charging and discharging at a voltage of about 2.0 V to about 4.25 V and a temperature of about 30° C. to about 50° C.

11. The method of claim 7, wherein activating the all-solid-state battery comprises subjecting the all-solid-state battery to 3 to 10 cycles of charging and discharging.

12. The method of claim 7, wherein activating the all-solid-state battery comprises applying a pressure of about 10 MPa or less to the all-solid-state battery.

13. The method of claim 7, wherein operating the activated all-solid-state battery comprises charging and discharging while applying a pressure of about 2.5 MPa to about 4.5 MPa to the activated all-solid-state battery.

14. A method of testing an all-solid-state battery, the method comprising:
preparing an all-solid-state battery comprising a cathode layer, an anode layer, and a solid electrolyte layer interposed between the cathode layer and the anode layer;
activating the all-solid-state battery by charging and discharging while applying a pressure of about 4.5 MPa or more to the all-solid-state battery and;
operating an activated all-solid-state battery while applying a pressure of about 4.5 MPa or less to the activated all-solid-state battery; and
determining whether the all-solid-state battery is defective or not by measuring a DC-IR (direct current-internal resistance) value of an operated all-solid-state battery.

15. The method of claim 14, wherein the anode layer comprises:
about 60 wt % to about 80 wt % of a silicon-based anode active material,
about 10 wt % to about 35 wt % of a solid electrolyte, and
about 1 wt % to about 10 wt % of a binder.

16. The method of claim 14, wherein the all-solid-state battery has an N/P ratio of about 2.0 or less but greater than about 1.1.

17. The method of claim 14, wherein activating the all-solid-state battery comprises applying pressure to the all-solid-state battery and charging and discharging at a voltage of about 2.0 V to about 4.25 V and a temperature of about 30° C. to about 50° C.

18. The method of claim 14, wherein activating the all-solid-state battery comprises applying a pressure of about 10 MPa or less to the all-solid-state battery and subjecting the all-solid-state battery to 3 to 10 cycles of charging and discharging.

19. The method of claim 14, wherein operating the activated all-solid-state battery comprises charging and discharging while applying a pressure of about 2.5 MPa to about 4.5 MPa to the activated all-solid-state battery.

20. The method of claim 14, wherein the activated all-solid-state battery is determined to be defective if the DC-IR value is about 50Ω or more in first-cycle discharging, after operating the activated all-solid-state battery.
